(19) United States
(12) Patent Application Publication
(10) Pub. No.: US 2025/0006489 A1
(43) Pub. Date: Jan. 2, 2025

(54) METHODS AND ASSEMBLIES FOR DEPOSITING MATERIAL IN A GAP

(71) Applicant: ASM IP Holding B.V., Almere (NL)

(72) Inventors: Ranjit Borude, Tokyo (JP); Bablu Mukherjee, Hyderabad Telangana (IN); René Henricus Jozef Vervuurt, Leuven (BE); Viljami Pore, Helsinki (FI); Takayoshi Tsutsumi, Nagoya-shi Aichi (JP); Nobuyoshi Kobayashi, Tokyo (JP); Masaru Hori, Nisshin-shi Aichi (JP)

(21) Appl. No.: 18/754,246

(22) Filed: Jun. 26, 2024

Related U.S. Application Data
(60) Provisional application No. 63/523,935, filed on Jun. 29, 2023.

(51) Int. Cl. H01L 21/02; C23C 16/30; C23C 16/32; C23C 16/34; C23C 16/40; C23C 16/455; C23C 16/517; H01J 37/32

(52) U.S. Cl. CPC H01L 21/02274; C23C 16/45536; C23C 16/517; H01J 37/32357; H01L 21/02211; C23C 16/30; C23C 16/325; C23C 16/345; C23C 16/401; H01J 2237/332; H01L 21/02126; H01L 21/02164; H01L 21/02167; H01L 21/0217

(57) ABSTRACT

The disclosure relates to methods of depositing a material comprising silicon in a gap. The method comprises providing a substrate, the substrate comprising the gap, wherein the gap comprises an inner surface and exposing the substrate to a first plasma having high ion energy to modify predetermined areas of the gap inner surface. The method further comprises exposing the substrate to a second plasma having low ion energy to passivate the modified areas of the gap surface to form passivated modified areas on the gap surface and contacting the substrate with a vapor-phase silicon precursor to chemisorb the silicon precursor on unmodified areas of the gap for depositing material comprising silicon on the unmodified areas. The current disclosure further relates to a method of controlling chemisorption of a vapor-phase silicon precursor on a substrate, and to a semiconductor processing assembly for performing the methods according to the current disclosure.

### CROSS-REFERENCE TO RELATED APPLICATIONS

This application claims priority to and the benefit of U.S. Provisional Application No. 63/523,935, filed Jun. 29, 2023, the entirety of which is incorporated by reference herein.

### FIELD

The present disclosure generally relates to methods and assemblies for processing semiconductor substrates. More particularly, the disclosure relates to methods and assemblies for selectively depositing a silicon-comprising material on a semiconductor substrate.

### BACKGROUND

Silicon oxide is used for various purposes in semiconductor devices. The ever-decreasing device size requires continuously improved control on growth rate and topological selectivity to allow for the manufacture of such devices. Cyclic deposition methods, such as atomic layer deposition and cyclic chemical vapor deposition may offer solutions to many of the challenges faced by the industry. Specifically, plasma-enhanced methods may be suitable as they allow for the use of low temperatures, and are thus compatible with low thermal budgets of complicated devices.

Although various plasma-enhanced methods have been developed in the art, the inventors have recognized a continued need for more versatile and tunable methods to deposit silicon-containing materials on substrates.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing a material comprising silicon in a gap and methods of controlling chemisorption of a vapor-phase silicon precursor on a substrate. Embodiments of the current disclosure further relate to methods of fabricating semiconductor devices, semiconductor devices, and to semiconductor processing assemblies.

In one aspect, a method of depositing a material comprising silicon in a gap is disclosed. The method comprises providing a substrate, the substrate comprising the gap, wherein the gap comprises an inner surface, and exposing the substrate to a first plasma having high ion energy to modify predetermined areas of the gap inner surface. The method further comprises exposing the substrate to a second plasma having low ion energy to passivate the modified areas of the gap surface to form passivated modified areas on the gap surface and contacting the substrate with a vapor-phase silicon precursor to chemisorb the silicon precursor on unmodified areas of the gap for depositing material comprising silicon on the unmodified areas.

In some embodiments, the substrate is provided in a reaction chamber, and the substrate is exposed to the first plasma and the second plasma in the reaction chamber.

In some embodiments, the passivation of the modified areas comprises forming nitrogen-comprising terminations.

In some embodiments, the first plasma is generated from a gas selected from a group consisting of N, He, Ne, Ar, Kr and Xe. In some embodiments, the second plasma comprises nitrogen. In some embodiments, the second plasma is generated from a gas comprising at least one of N₂, NH₃ and H₂N₄. In some embodiments, the second plasma is generated from a gas comprising at least one of He, Ne, Ar, Kr and Xe.

In some embodiments, the ion energy of the first plasma is at least about 15 eV. In some embodiments, the ion energy of the second plasma is at most 5 eV.

In some embodiments, the gap inner surface comprises an oxide surface. In some embodiments, the substrate comprises a silicon nitride surface.

In some embodiments, the silicon precursor is a nitrogen-comprising silane comprising from 1 to 4 silicon atoms. In some embodiments, the silicon precursor is represented by the formula Siₐ(NR₂)_{b}X_{c}, wherein a is 1, 2, 3 or 4, b+c=2a+2, b is at least 1, each R is independently selected from H, methyl, ethyl, isopropyl, tert-butyl and phenyl, and each X is independently selected from H, methyl, ethyl, isopropyl, tert-butyl, phenyl, F, Cl, Br and I. In some embodiments, the silicon precursor is selected from a group consisting of SiH₃[N(CH₃)₂], SiH₃[N(CH₂CH₃)₂], SiH₃[N(CH₃)(CH₂CH₃)], SiH₃[N(C(CH₃)₃)₂], SiH₃[N(CH(CH₃)₂)₂], SiH₂[N(CH₃)₂]₂, SiH₂[N(CH₂CH₃)₂]₂, SiH₂[N(CH₃)(CH₂CH₃)]2, SiH₂[N(C(CH₃)₃)₂]₂, SiH₂[N(CH(CH₃)₂)₂]₂, SiH(CH₃)[N(CH₃)₂]₂, SiH(CH₃)[N(CH₂CH₃)₂]₂, SiH(CH₃)[N(CH₃)(CH₂CH₃)]₂, SiH(CH₃)[N(C(CH₃)₃)₂]₂, SiH(CH₃)[N(CH(CH₃)₂)₂]₂, Si(CH₃)₂[N(CH₃)₂]₂, Si(CH₃)₂[N(CH₂CH₃)₂]₂, Si(CH₃)₂[N(CH₃)(CH₂CH₃)]₂, Si(CH₃)₂[N(C(CH₃)₃)₂]₂, Si(CH₃)₂[N(CH(CH₃)₂)₂]₂, SiH[N(CH₃)₂]₃, SiH[N(CH₂CH₃)₂]₃, SiH[N(CH₃)(CH₂CH₃)]₃, SiH[N(C(CH₃)₃)₂]₃, SiH[N(CH(CH₃)₂)₂]₃, Si[N(CH₃)₂]₄, Si[N(CH₂CH₃)₂]₄, Si[N(C(CH₃)₃)₂]₄, Si[N(CH(CH₃)₂)₂]₄, SiCl[N(CH₃)₂]₃, SiCl[N(CH₂CH₃)₂]₃, SiCl[N(CH₃)(CH₂CH₃)]₃, SiCl[N(C(CH₃)₃)₂]₃, SiCl[N(CH(CH₃)₂)₂]₃, Si[NH(CH₃)]₃—Si[NH(CH₃)]₃, Si[NH(CH₂CH₃)]₃—Si[NH(CH₂CH₃)]₃, and SiH₂(NH(CH(CH₃)₂)₂—SiH₂.

In some embodiments, the gap comprises a bottom, and the predetermined area modified by the first high energy plasma is the bottom.

In some embodiments, the chemisorption of the silicon precursor is reduced by at least 60% on the passivated modified areas relative to the unmodified areas.

In some embodiments, the material comprising silicon is deposited conformally on unmodified areas of the gap. In some embodiments, the mater material comprising silicon at least partially fills the gap. In some embodiments, the gap is filled from the bottom of the gap upwards.

In another aspect, a method of controlling chemisorption of a vapor-phase silicon precursor on a substrate having a surface is disclosed. The method comprises providing the substrate in a reaction chamber, exposing the substrate to a first plasma having high ion energy to partially modify the surface, exposing the substrate to a second plasma having low ion energy to passivate the partially modified surface to form a partially passivated surface, and contacting the substrate with a vapor-phase silicon precursor to chemisorb the silicon precursor on the partially passivated surface for depositing material comprising silicon on the substrate.

In some embodiments of the method of controlling the chemisorption of a vapor-phase silicon precursor on a substrate, the substrate comprises a gap comprising an inner surface, and the first plasma partially modifies the inner surface of the gap.

In a further aspect, a semiconductor processing assembly is disclosed. The semiconductor processing assembly comprises a reaction chamber configured and arranged to hold a substrate, a first plasma gas source configured and arranged to contain a gas for generating at least one of a first plasma and a second plasma, a precursor source configured and arranged to contain and evaporate a silicon precursor and a plasma generation system for generating a first plasma and a second plasma. The semiconductor processing assembly further comprises an injection system constructed and arranged to provide the first plasma and the second plasma into the reaction chamber and to provide a vapor-phase silicon precursor into the reaction chamber in a vapor phase, an exhaust and a controller configured and arranged to cause the system to carry out a method according to the current disclosure.

In some embodiments, the processing assembly further comprises a second plasma gas source configured and arranged to contain a gas for generating the second of the first plasma and the second plasma.

In yet another aspect, a structure formed by the methods according to the current disclosure is disclosed.

In an additional aspect, a semiconductor device manufactured by using the methods according to the current disclosure is disclosed.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings:

FIG. 1 is a block diagram of exemplary embodiments of a method according to the current disclosure.

FIG. 2 is a block diagram of additional exemplary embodiments of a method according to the current disclosure.

FIG. 3 is a schematic presentation of exemplary embodiments of a method according to the current disclosure.

FIG. 4 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

The description of exemplary embodiments of methods, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

### Substrate

In one aspect, a method of depositing a material comprising silicon in a gap is disclosed. The method comprises providing a substrate, the substrate comprising the gap, wherein the gap comprises an inner surface. A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins is considered a gap. A gap may comprise a top and a bottom. An upper part of a gap is the area at the opening of the gap, and the bottom of the gap is the part of the gap distal to the opening of the gap. In some embodiments, the gap comprises a bottom, and the predetermined area modified by the first high energy plasma is the bottom. The area outside the gap is termed the top surface of a gap, such as the topmost horizontal part of a fin, or an area of the substrate between holes or vias. A gap may further have an inner surface (i.e. a sidewall). An inner surface is a surface connecting the top and bottom of a gap. An inner surface may be substantially vertical, or it may comprise slanted portions. Thus, the size of the gap opening at the top of the gap may be different than the area of the bottom of the gap.

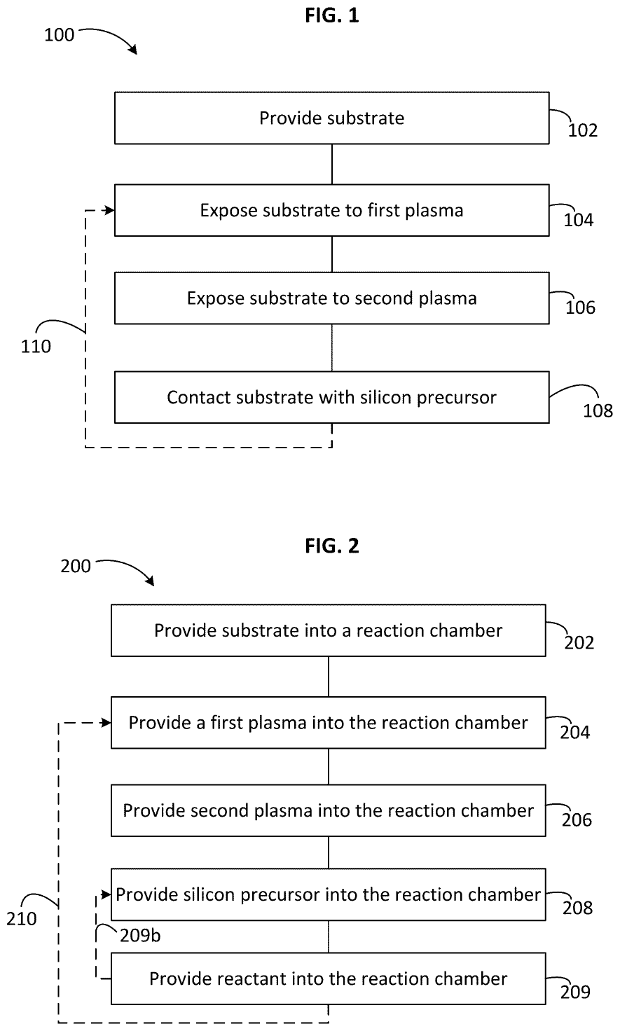

As indicated in FIG. 1, the deposition method 100 according to the current disclosure comprises providing a substrate 102. The substrate may be provided in a reaction chamber 202, as in the embodiments of the method 200 in FIG. 2. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate according to the current disclosure comprises a gap (such as a recess), and optionally other features, such as protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

In some embodiments, the substrate may be pretreated or cleaned prior to or at the beginning of the process according to the current disclosure. In some embodiments, the substrate may be subjected to a plasma cleaning process prior to or at the beginning of the process. In some embodiments, a pretreatment or cleaning process may be carried out in the same reaction chamber as the current process. However, in some embodiments, a pretreatment or cleaning process may be carried out in a separate reaction chamber.

In some embodiments, the gap inner surface comprises an oxide surface. In some embodiments, the oxide surface comprises, consists essentially of, or consists of, silicon oxide. In some embodiments, the oxide surface comprises, consists essentially of, or consists of, low k material. A low k material may be, for example, silicon-based material having a k value similar to, or lower than, that of silicon oxide. Examples of low k materials include SiC, SiCN, SiOC, SiON, and SiOCN. In some embodiments, the substrate comprises a silicon nitride surface. In some embodiments, the substrate surface comprises areas having different chemical composition. In some embodiments, the gap inner surface is chemically distinct from areas outside the gap. For example, in some embodiments, the gap inner surface is a silicon oxide surface and the substrate surface outside the gap comprises hard mask material, such as a metal oxide-based material. The surface of the substrate may comprise several materials, for example, when the substrate comprises partially manufactured semiconductor devices.

### Reaction Chamber

In some embodiments, the substrate is provided in a reaction chamber, and the substrate is exposed to the first plasma and the second plasma in the reaction chamber.

The method of depositing material comprising silicon in a gap according to the current disclosure may thus comprise providing a substrate in a reaction chamber. In other words, a substrate is in a space where the deposition conditions can be controlled. The reaction chamber may be a single wafer reactor. Alternatively, the reaction chamber may be a batch reactor. The reaction chamber 402 can form part of a semiconductor processing assembly 400 for manufacturing semiconductor devices, as depicted in FIG. 4. The semiconductor processing assembly 400 may comprise one or more multi-station processing chambers. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the substrate is exposed to the first plasma and to the second plasma and contacted with the silicon precursor in the same reaction chamber. In some embodiments, at least two of exposing the substrate to first plasma, exposing the substrate to second plasma and contacting the substrate with a silicon precursor are performed in one reaction chamber. In some embodiments, the substrate is exposed to the first plasma and to the second plasma and contacted with the silicon precursor in different processing stations of a multi-station chamber. In some embodiments, the substrate is exposed to the first plasma and to the second plasma and contacted with the silicon precursor in the same cluster tool.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer ALD (atomic layer deposition) reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of a semiconductor processing assembly, such as an atomic layer deposition (ALD) assembly. The reaction chamber can form part of a chemical vapor deposition (CVD) assembly. The semiconductor processing assembly may be an ALD or a CVD deposition assembly, but in certain process steps, molecular layer deposition (MLD) may also be employed in some parts of the deposition process flows. Further, the semiconductor processing assembly may be configured and arranged for etching processes. In some embodiments, the method is performed in a single reaction chamber of a cluster tool, but other, preceding or subsequent, manufacturing steps of the structure or device are performed in additional reaction chambers of the same cluster tool. Optionally, a semiconductor processing assembly including the reaction chamber can be provided with a heater to activate the reactions by elevating the temperature of one or more of the substrates and/or the reactants and/or precursors.

### First Plasma

In the methods according to the current disclosure, the substrate is exposed to a first plasma and subsequently to a second plasma, as indicated in FIGS. 1 and 2 (blocks 104, 204 and 106, 206, respectively). The first plasma has higher ion energy than the second plasma. The first plasma is able to remove active groups from the surface of the substrate. For example, —OH groups may be removed. In some embodiments, the substrate surface comprises silicon oxide, and the first plasma removes —OH terminations and exposes the substrate to a first plasma having high ion energy to modify predetermined areas of the gap inner surface. In addition to removing active groups, dangling bonds may be formed on or in the substrate.

The design of a processing unit, such as a reaction chamber, influences the specific parameters selected for the first plasma and second plasma exposures according to the current disclosure. For example, pressure, plasma power and gap size may be adjusted to obtain a suitable plasma ion energy, and desired results. Further, the duration of a plasma exposure may be varied. In some embodiments, the duration of a plasma exposure is longer than about 1 second (s), longer than about 5 s, longer than about 10 s, longer than about 30 s or longer than about 40 s. In some embodiments, the duration of a plasma exposure is shorter than about 60 s, shorter than about 45 s, shorter than about 30 s, shorter than about 20 s, shorter than about 10 s, shorter than about 5 s or shorter than about 1 s. In some embodiments, a first plasma or a second plasma exposure may have a duration of from about 0.5 s to about 60 s, such as from about 1 s to 30 s, from about 1 s to about 15 s, from about 10 s to about 50 s or from about 10 to about 20 s, such as about 0.5 s, 1 s, 3 s, 4 s, 8 s, 15 s, 30 s or 45 s.

In some embodiments, the ion energy of the first plasma is at least about 15 eV. In some embodiments, the ion energy of the first plasma is at least about 20 eV. In some embodiments, the ion energy of the first plasma is at least about 25 eV. In some embodiments, the ion energy of the first plasma is at least about 40 eV.

Among other things, plasma ion energy may be influenced by pressure. In some embodiments, the substrate is held at a pressure of from about 5 Pa to about 1000 Pa during exposure to the first plasma. In some embodiments, the substrate is held at a pressure of below 1,000 Pa during exposure to the first plasma. Suitable pressure will depend on the reaction chamber configuration. In some embodiments, the substrate is held at a pressure of from about 5 Pa to about 50 Pa or at a pressure of from about 5 Pa to about 30 Pa or at a pressure of from about 5 Pa to about 15 Pa during exposure to the first plasma. However, in some other embodiments, the substrate is held at a pressure of from about 1,000 Pa to about 3,000 Pa or at a pressure of from about 1,000 Pa to about 6,700 Pa or at a pressure of from about 1,000 Pa to about 2,000 Pa during exposure to the first plasma. In some embodiments, the ion energy of the first plasma and the second plasma is regulated by altering the pressure in a reaction chamber. In some embodiments, the pressure in the reaction chambers during exposing the substrate to first plasma is lower than during exposing the substrate to second plasma. In some embodiments, the substrate is held at a pressure that is at least three times, or at least four times, at least five times or at least six times higher during the second plasma exposure than during the first plasma exposure.

In some embodiments of the disclosure, an individual plasma pulse, employed in the generation of reactive species, can be split into a number of constituent micropulses. For example, a number of micropulses may employed as an alternative to an individual static steady state plasma pulse, and such micropulses may comprise a duty cycle between 10% to 90% (RF power on-time), with a plasma frequency of between 10 Hz and 100000 Hz.

In some embodiments, the first plasma is generated from gases selected from a group consisting of nitrogen (N₂) and noble gases. By noble gases according to the current disclosure is meant helium (He), neon (Ne), argon (Ar), krypton (Kr) and xenon (Xe). In some embodiments, the first plasma is generated from a gas selected from a group consisting of N, He, Ne and Ar. In some embodiments, the gas used for generating first plasma consists substantially of nitrogen. In some embodiments, the gas used for generating first plasma consists substantially of nitrogen and one noble gas.

In some embodiments, the first plasma and the second plasma are generated from the same gas stream. In some embodiments, the first plasma and the second plasma are generated from gases having different compositions. A gas in the current disclosure may be a mixture of gases. In this disclosure, “gas” can include material that is a gas at normal temperature and pressure (NTP), a vaporized solid and/or a vaporized liquid, and can be constituted by a single gas or a mixture of gases, depending on the context. A passivation material precursor may be provided to the reaction chamber in gas phase. A hard mask precursor may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas. A gas, including an inert gas, may be used to generate plasma from it.

### Second Plasma

The method further comprises exposing the substrate to a second plasma, as indicated in blocs 106 and 206 of FIGS. 1 and 2, respectively. The second plasma has a lower ion energy (low ion energy plasma) to passivate the modified areas of the gap surface to form passivated modified areas on the gap surface.

In some embodiments, the first plasma is nitrogen (N) plasma, and the second plasma is N plasma. In some embodiments, the first plasma is a mixture of N and Ar, and the second plasma is a mixture of N and Ar. I some embodiments, the first plasma is a mixture of N and He, and the second plasma is a mixture of N and He. In some embodiments, the first plasma is Ar plasma, and the second plasma is N plasma, or a mixture of N and another gas. By nitrogen plasma is meant plasma generated from nitrogen gas. Corresponding naming is used for other plasmas, such as argon plasma and helium plasma.

In some embodiments, the substrate is held at a pressure of at least about 10 Pa during exposure to the second plasma, such as at a pressure of about 15 Pa. In some embodiments, the substrate is held at a pressure of at least about 20 Pa, such as at a pressure of about 25 Pa or 30 Pa during exposure to the second plasma. In some embodiments, the substrate is held at a pressure of at least about 100 Pa, such as about 120 Pa during exposure to the second plasma. In some embodiments, the substrate is held at a pressure of at least about 150 Pa during exposure to the second plasma. However, in some other embodiments, the substrate is held at a pressure of from about 2,500 Pa to about 15,000 Pa during exposure to the second plasma. In some embodiments, the substrate is held at a pressure of above 1,000 Pa during exposure to the second plasma.

In some embodiments, the passivation of the modified areas comprises forming nitrogen-comprising terminations. In some embodiments, the nitrogen-comprising terminations are —NH terminations. In some embodiments, the second plasma comprises nitrogen. In some embodiments, the second plasma is generated from a gas comprising at least one of N₂, NH₃, hydrazine (N₂H₄) and alkyl-hydrazine derivates In some embodiments, the second plasma is generated from a gas comprising nitrogen and at least one of He, Ne, Ar, Kr and Xe. In some embodiments, the gas used for generating second plasma consists substantially of nitrogen. In some embodiments, the gas used for generating second plasma consists substantially of nitrogen and one noble gas.

In some embodiments, the ion energy of the second plasma is at most 5 eV. In some embodiments, the ion energy of the second plasma is at most 8 eV. In some embodiments, the ion energy of the second plasma is at most 10 eV. In some embodiments, the ion energy of the second plasma is between 4 eV and 10 eV.

### Plasma Generation

The first plasma and the second plasma may be generated in various ways. At least one of the first plasma and the second plasma may be direct plasma. At least one of the first plasma and the second plasma may be remote plasma. The plasma may be generated by radio frequency (RF plasma), by microwaves (microwave plasma) or by electric current (e.g. inductively-coupled plasma).

When direct plasma is employed, plasma is generated within the reaction chamber. In such embodiments, the methods of the present disclosure can be executed in an apparatus comprising two electrodes between which the substrate is positioned. The electrodes can be positioned parallel at a pre-determined distance called an electrode gap. In some embodiments, the electrode gap can be at least 5 mm to at most 30 mm, at least 5 mm to at most 10 mm, or at least 10 mm to at most 20 mm, or of at least 20 mm to at most 30 mm.

In some embodiments, a plasma frequency of at least 40 kHz to at most 2.45 GHz can be used for generating first plasma and/or second plasma, or a plasma frequency of at least 40 kHz to at most 80 kHz can be used, or a plasma frequency of at least 80 kHz to at most 160 kHz can be used, or a plasma frequency of at least 160 kHz to at most 320 kHz can be used, or a plasma frequency of at least 320 kHz to at most 640 kHz can be used, or a plasma frequency of at least 640 kHz to at most 1280 kHz can be used, or a plasma frequency of at least 1280 kHz to at most 2500 kHz can be used, or a plasma frequency of at least 2.5 MHz to at least 5 MHz can be used, or a plasma frequency of at least 5 MHz to at most 60 MHz can be used, or a plasma frequency of at least 5 MHz to at most 10 MHz can be used, or a plasma frequency of at least 10 MHz to at most 20 MHz can be used, or a plasma frequency of at least 20 MHz to at most 30 MHz can be used, or a plasma frequency of at least 30 MHz to at most 40 MHz can be used, or a plasma frequency of at least 40 MHz to at most 50 MHz can be used, or a plasma frequency of at least 50 MHz to at most 100 MHz can be used, or a plasma frequency of at least 100 MHz to at most 200 MHz can be used, or a plasma frequency of at least 200 MHz to at most 500 MHz can be used, or a plasma frequency of at least 500 MHz to at most 1000 MHz can be used, or a plasma frequency of at least 1 GHz to at most 2.45 GHz can be used. In exemplary embodiments, the plasma can be an RF plasma, and RF power can be provided at a frequency of 13.56 MHz. In further exemplary embodiments, the plasma can be an RF plasma, and RF power can be provided at a frequency of 60 MHz.

In some embodiments, a plasma exposure can be split into a number of constituent micropulses. For example, a number of micropulses may employed as an alternative to an individual static steady state plasma exposure, and such micropulses may comprise a duty cycle between 10% to 90% (RF power on-time), with a plasma frequency of between 10 Hz and 100,000 Hz.

### Silicon Precursor

After the substrate is exposed to first plasma and to second plasma, the substrate is contacted with a vapor-phase silicon precursor, as indicated in blocks 108 and 208 in FIGS. 1 and 2, respectively. Contacting of the substrate with the silicon precursor may be performed by providing the silicon precursor into a reaction chamber as in the embodiments of FIG. 2. The silicon precursor will chemisorb on unmodified areas of the gap for depositing material comprising silicon on the unmodified areas. Without limiting the current disclosure to any specific theory, the chemisorption of the silicon precursor may be reduced due to the exposure to first plasma and second plasma. In some embodiments, the plasma exposures may reduce the chemisorption of the silicon precursor to the passivated areas. The degree to which chemisorption is reduced may be adjusted by selection of the plasma exposure conditions. In some embodiments, the plasma exposures may inhibit the chemisorption of the silicon precursor to the passivated areas substantially completely.

In some embodiments, the chemisorption of the silicon precursor is reduced by at least 60% on the passivated modified areas relative to the unmodified areas. For example, using He plasma as the first plasma and N plasma as the second plasma, the chemisorption of the silicon precursor may be reduced by about 87%. In another example, in which N plasma was used as both the first plasma and the second plasma, the chemisorption of the silicon precursor was reduced by about 71%.

In some embodiments, the material comprising silicon is deposited conformally on unmodified areas of the gap. In some embodiments, the mater material comprising silicon at least partially fills the gap. In some embodiments, the gap is filled from the bottom of the gap upwards.

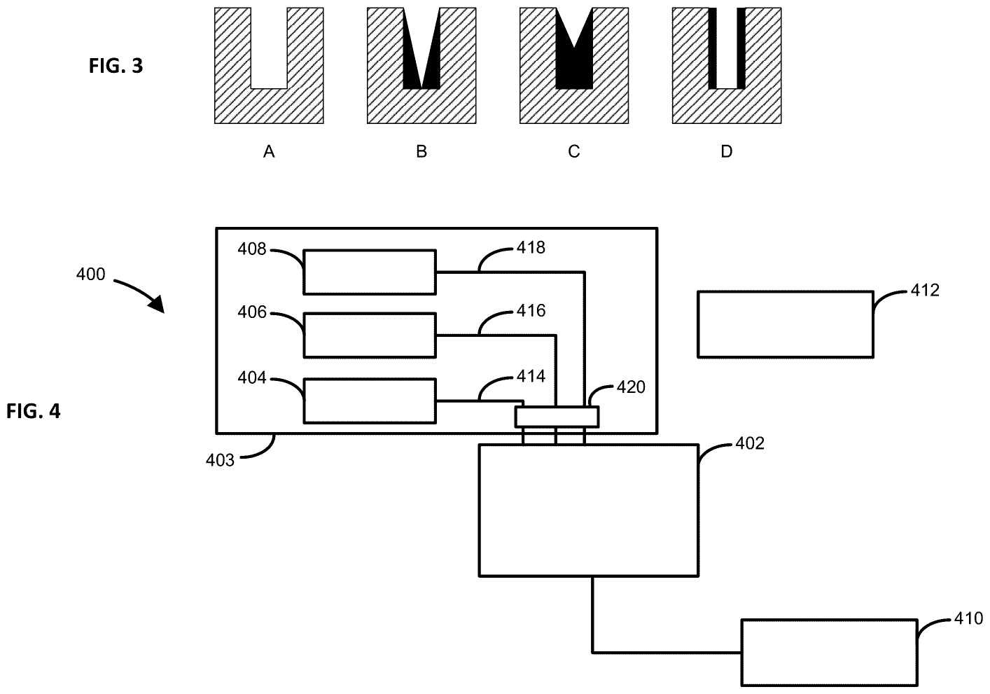

FIG. 3 depicts a gap into which material comprising silicon is deposited. In panel A of FIG. 3, an empty gap is indicated. In panel B, the material comprising silicon is deposited preferentially at the bottom of the gap. In such embodiments, the inhibition of silicon precursor chemisorption may be most prevalent closer to a gap opening relative to a gap bottom. In panel C, the gap is filled substantially in a bottom-up manner, as the deposition of material comprising silicon continues to be faster towards the bottom of the gap. In panel D, the material comprising silicon is deposited substantially evenly across a wall of the gap. In such embodiments, the plasma treatments inhibit the chemisorption of the silicon precursor substantially only at the bottom of the gap. Embodiments similar to the one indicated in panel D, may be useful in depositing thin layers on the sidewalls of gaps having small critical dimensions. For example, it may be envisaged that the rate of deposition is reduced along the sidewall of the gap, and the deposition is substantially fully inhibited at the bottom of the gap. This may allow careful thickness control of the deposition on the sidewall, which may be useful in some applications.

In some embodiments, the silicon precursor comprises silicon and nitrogen. In some embodiments, the silicon precursor comprises silicon and carbon. In some embodiments, the silicon precursor comprises silicon, carbon and nitrogen. In some embodiments, the silicon precursor comprises silicon, carbon and oxygen. In some embodiments, the silicon precursor comprises silicon and oxygen. In some embodiments, the silicon precursor comprises silicon, oxygen and nitrogen. In some embodiments, the silicon precursor comprises silicon, carbon, oxygen and nitrogen. In some embodiments, the silicon precursor consists of silicon, carbon and hydrogen. In some embodiments, the silicon precursor contains a silicon-nitrogen bond. In some embodiments, the silicon precursor contains only one silicon atom. In some embodiments, the silicon precursor contains at most two silicon atoms. In some embodiments, the silicon precursor contains at most three silicon atoms. In some embodiments, the silicon precursor contains two silicon atoms. In some embodiments, the silicon precursor contains three silicon atoms.

In some embodiments, the silicon precursor is a nitrogen-comprising silane comprising from 1 to 4 silicon atoms. In some embodiments, the silicon precursor is an alkylaminosilane. In some embodiments, the silicon precursor is an alkylaminosilane having one silicon atom. In some embodiments, the silicon precursor is an alkylaminodisilane. In some embodiments, the silicon precursor is an alkylaminotrisilane. In some embodiments, the silicon precursor is an alkylaminotetrasilane. Alkylaminosilanes according to the current disclosure may comprise from one to four alkylamino groups. For example, alkylaiminosilane may comprise at most three alkylamino groups or at most three alkylamino groups. Examples of alkylaminosilanes according to the current disclosure include (NH₂R)₃SiH, (NH₂R)₂SiH₂, (NH₂R)SiH₃, wherein each R is independently selected from linear and branched C1 to C5 alkyls. In some embodiments, at least one R is saturated. In some embodiments, all R are saturated. In some embodiments, at least one R is unsaturated. In some embodiments, all R are unsaturated.

In some embodiments, the silicon precursor is represented by formula Siₐ(NR₂)_{b}X_{c}, wherein a is 1, 2, 3 or 4, b+c=2a+2, b is at least 1, each R is independently selected from H, methyl, ethyl, isopropyl, tert-butyl and phenyl, and each X is independently selected from H, methyl, ethyl, isopropyl, tert-butyl, phenyl, F, Cl, Br and I. In some embodiments, the silicon precursor is selected from a group consisting of SiH₃[N(CH₃)₂], SiH₃[N(CH₂CH₃)₂], SiH₃[N(CH₃)(CH₂CH₃)], SiH₃[N(C(CH₃)₃)₂], SiH₃[N(CH(CH₃)₂)₂], SiH₂[N(CH₃)₂]₂, SiH₂[N(CH₂CH₃)₂]₂, SiH₂[N(CH₃)(CH₂CH₃)]₂, SiH₂[N(C(CH₃)₃)₂]₂, SiH₂[N(CH(CH₃)₂)₂]₂, SiH(CH₃)[N(CH₃)₂]₂, SiH(CH₃)[N(CH₂CH₃)₂]₂, SiH(CH₃)[N(CH₃)(CH₂CH₃)]₂, SiH(CH₃)[N(C(CH₃)₃)₂]₂, SiH(CH₃)[N(CH(CH₃)₂)₂]₂, Si(CH₃)₂[N(CH₃)₂]₂, Si(CH₃)₂[N(CH₂CH₃)₂]₂, Si(CH₃)₂[N(CH₃)(CH₂CH₃)]₂, Si(CH₃)₂[N(C(CH₃)₃)₂]₂, Si(CH₃)₂[N(CH(CH₃)₂)₂]₂, SiH[N(CH₃)₂]₃, SiH[N(CH₂CH₃)₂]₃, SiH[N(CH₃)(CH₂CH₃)]₃, SiH[N(C(CH₃)₃)₂]₃, SiH[N(CH(CH₃)₂)₂]₃, Si[N(CH₃)₂]₄, Si[N(CH₂CH₃)₂]₄, Si[N(C(CH₃)₃)₂]₄, Si[N(CH(CH₃)₂)₂]₄, SiCl[N(CH₃)₂]₃, SiCl[N(CH₂CH₃)₂]₃, SiCl[N(CH₃)(CH₂CH₃)]₃, SiCl[N(C(CH₃)₃)₂]₃, SiCl[N(CH(CH₃)₂)₂]₃, Si[NH(CH₃)]₃—Si[NH(CH₃)]₃, Si[NH(CH₂CH₃)]₃—Si[NH(CH₂CH₃)]₃, and SiH₂(NH(CH(CH₃)₂)₂—SiH₂.

Alkylaminosilanes according to the current disclosure may comprise from one to four alkylamino groups. In embodiments, in which the alkylaiminosilane comprises at most three alkylamino groups, the additional groups may be alkyl groups or alkoxy groups, for example.

In another aspect, a method of controlling chemisorption of a vapor-phase silicon precursor on a substrate having a surface is disclosed. The method comprises providing the substrate in a reaction chamber, exposing the substrate to a first plasma having high ion energy to partially modify the surface, exposing the substrate to a second plasma having low ion energy to passivate the partially modified surface to form a partially passivated surface and contacting the substrate with a vapor-phase silicon precursor to chemisorb the silicon precursor on the partially passivated surface for depositing material comprising silicon on the substrate.

In some embodiments of the method of controlling the chemisorption of a vapor-phase silicon precursor on a substrate, the substrate comprises a gap comprising an inner surface, and the first plasma partially modifies the inner surface of the gap.

### Deposited Material

The material that is deposited in the gap comprises silicon. Material comprising silicon may be understood to contain silicon and at least another compound, such as oxygen, carbon or nitrogen. The deposited material may be silicon oxide. The deposited material may be silicon-comprising low k material. In some embodiments, the material comprising silicon comprises —OH termination. In some embodiments, the material comprising silicon is silicon oxide. As used herein, silicon oxide refers to a material that includes silicon and oxygen. Silicon oxide can be represented by the formula SiOₓ, where x can be between 0 and 2 (e.g., SiO₂). In some cases, the silicon oxide may not include stoichiometric silicon oxide. In some cases, the silicon oxide can include other elements, such as carbon, nitrogen, hydrogen, or the like. In some embodiments, the material comprising silicon is silicon nitride. Silicon nitride (SiN) can refer to a material that includes silicon and nitrogen. Silicon nitride need not necessarily be a stoichiometric composition. An amount of silicon can range from 5 to 50 at %, and amount of nitrogen can range from about 50 to about 95 at %. In some embodiments, SiN comprises one or more elements in addition to Si and N, such as H or C. In some embodiments, the material comprising silicon is silicon carbide. Silicon carbide (SiC) can refer to a material that includes silicon and carbon. Silicon carbide need not necessarily be a stoichiometric composition. An amount of silicon can range from 5 to 50 at % and an amount of carbon can range from about 50 to about 95 at %. In some embodiments, SiC comprises one or more elements in addition to Si and C, such as H or N. In some embodiments, the material comprising silicon is silicon oxycarbide. Silicon oxycarbide (SiOC) can refer to material that comprises silicon, oxygen, and carbon. As used herein, unless stated otherwise, SiOC is not intended to limit, restrict, or define the bonding or chemical state, for example, the oxidation state of any of Si, O, C, and/or any other element in the material. In some embodiments, SiOC comprises one or more elements in addition to Si, O, and C, such as H or N. In some embodiments, SiOC comprises Si—C bonds and/or Si—O bonds. In some embodiments, SiOC comprises Si—C bonds and Si—O bonds and does not comprise Si—N bonds. In some embodiments, SiOC comprises Si—H bonds in addition to Si—C and/or Si—O bonds. In some embodiments, SiOC comprises —OH termination. In some embodiments, SiOC does not comprise nitrogen. In some other embodiments, SiOC comprises from about 0% to about 40% nitrogen on an atomic basis (at %). By way of particular examples, SiOC can be or include a layer comprising SiOCN. In some embodiments, silicon oxycarbide can be represented by the chemical formula Si₇OₓC_{y}, where z can range from about 0 to about 2, x can range from about 0 to about 2, and y can range from about 0 to about 5. Silicon oxycarbonitride (SiOCN) refers to material that comprises silicon, oxygen, nitrogen and carbon. As used herein, unless stated otherwise, SiOCN is not intended to limit, restrict, or define the bonding or chemical state, for example, the oxidation state of any of Si, O, C, N and/or any other element in the material. In some embodiments, SiOCN comprises —OH termination. In some embodiments, SiOCN is material that can be represented by the chemical formula Si₇OₓC_{y}N_{w}, where z can range from about 0 to about 2, x can range from about 0 to about 2, y can range from about 0 to about 2, and w can range from about 0 to about 2.

Although the material comprising silicon is deposited in the gap, it may also be deposited on the surface of the substrate, depending on the topology of the substrate. This may be wanted or unwanted, and additional processing steps may be utilized to remove the material comprising silicon from areas outside the gap, if needed.

### Cyclic Process

In some embodiments, the deposition process according to the current disclosure is a cyclic process. Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material), such as in phases 108 and 208 of FIGS. 1 and 2, respectively. In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the chemisorbed precursor. Purging steps may be utilized during one or more cycles, e.g., during each step of each cycle, to remove any excess precursor from the reaction space, such as the reaction chamber and/or remove any excess reactant and/or reaction byproducts from the reaction space, such as the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing a first precursor into the reaction chamber, and after providing a second precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

The process may comprise one or more cyclic phases. In some embodiments, the process comprises one or more acyclic (i.e. continuous) phases. In some embodiments, the deposition process comprises the continuous flow of at least one precursor. In such an embodiment, the process comprises a continuous flow of a first polymer precursor or second polymer precursor. In some embodiments, one or more of the precursors are provided in the reaction chamber continuously.

In the embodiment of FIG. 1, the deposition process may comprise loop 110, in which the exposure to first plasma is repeated after contacting the substrate with the silicon precursor. The process of FIG. 1 may or may not comprise contacting the substrate with a second precursor between contacting the substrate with the silicon precursor and repeating the exposure to first plasma. In embodiments, in which the substrate is not contacted with a second precursor or a reactant, the deposition process may be cyclic CVD, and the material comprising silicon is based on the silicon precursor. Embodiments, in which the method comprises contacting the substrate with a second precursor or a reactant, may be cyclic CVD processes or ALD processes, depending on the precursor(s) and the conditions in the reaction space, such as reaction chamber.

Loop 110 is optional, and thus in some embodiments, the process may be a non-cyclic process. For example, the process may be a CVD-type process. CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor, such as the silicon precursor, may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

In the embodiments of FIG. 2, the process comprises providing a silicon precursor 208 and a reactant 209 into the reaction chamber. In some embodiments, the silicon precursor and the reactant are provided into the reaction chamber alternately and sequentially. However, in some embodiments, providing the silicon precursor and the reactant into the reaction chamber may overlap at least partially. Providing the silicon precursor and the reactant may be repeated, indicated by loop 209b in FIG. 2. The number of repetitions 209b may be adjusted according to the amount of material comprising silicon to be deposited. Thus, in some embodiments, the cyclic process according to the current disclosure may be an ALD process.

Also in the embodiments of FIG. 2, the inhibition of the silicon precursor may be renewed, as indicated by loop 210. Similarly to FIG. 1, the mode of deposition (i.e. gapfill or conformal, or something in between) and/or the speed of deposition may be influenced by the intervals of cycling back to phase 204 by loop 210 (or to phase 104 by loop 110 in FIG. 1).

In a further aspect, a semiconductor processing assembly is disclosed, as indicated in FIG. 4. The semiconductor processing assembly comprises a reaction chamber configured and arranged to hold a substrate, a first plasma gas source configured and arranged to contain a gas for generating at least one of a first plasma and a second plasma, a silicon precursor source configured and arranged to contain and evaporate a silicon precursor and a plasma generation system for generating a first plasma and a second plasma. The semiconductor processing assembly further comprises an injection system constructed and arranged to provide the first plasma and the second plasma into the reaction chamber and to provide a vapor-phase silicon precursor into the reaction chamber in a vapor phase, an exhaust and a controller configured and arranged to cause the system to carry out a method according to the current disclosure. The injection system may fluidly couple the sources to the reaction chamber.

In yet another aspect, as indicated in FIG. 4, a semiconductor processing assembly 400 for depositing material comprising silicon in a gap is disclosed. The semiconductor processing assembly 400 comprises one or more reaction chambers 402 constructed and arranged to hold the substrate, an injection system 403 constructed and arranged to provide the first plasma and the second plasma into the reaction chamber 402, and to provide vapor-phase silicon precursor into the reaction chamber in a vapor phase. The semiconductor processing assembly 400 further comprises a first plasma gas source 404 constructed and arranged to contain the first plasma gas, a silicon precursor source 406 constructed and arranged to contain the silicon precursor and an optional second plasma gas source 408 constructed and arranged to contain a second plasma gas. The semiconductor processing assembly further comprises a plasma generation system 420 for generating a first plasma and a second plasma. As described above, the first plasma and the second plasma may be generated from the same plasma gas—held in a first plasma gas sources 404. In some embodiments, however, the second plasma is generated from a second plasma gas, which is held in a second plasma gas source 406.

The plasma generation system 420 is depicted to be along the lines 414-418. Such configurations are typical of remote plasma generation. However, as described above, direct plasma may be used in the processes according to the current disclosure. Therefore, it is to be understood that the plasma generation system 420 may alternatively be inside the reaction chamber 402, or otherwise integrated into the reaction chamber 402. For example, the reaction chamber may comprise a substrate support and an upper electrode, the substrate support comprising a lower electrode. In some embodiments, the semiconductor processing assembly according to the current disclosure comprises, consists essentially of, or consists of more than one plasma generation system. For example, the assembly may comprise a remote plasma and a direct plasma generation system.

The silicon precursor may be provided into the reaction chamber 402 through a thermal process, or through a plasma process. Especially certain plasma-enhanced CVD processes may involve generating plasma at the same time as providing the silicon precursor into the reaction chamber. Therefore, in FIG. 4, the plasma generation system 420, is indicated to extend over line 416.

The semiconductor processing assembly 400 is constructed and arranged to provide the silicon precursor and the optional reactant via the injection system 403 into the reaction chamber 402 for depositing material comprising silicon in a gap of a substrate.

In some embodiments, the semiconductor processing assembly 400 further comprises one or more additional precursor or reactant sources (not depicted in FIG. 4), and the injection system 403 is constructed and arranged to provide one or more reactants into the reaction chamber in a vapor phase. Further, the semiconductor processing assembly may comprise any number of additional sources for various treatments that may be a part of a given process flow performed in the assembly.

The processing assembly 400 can be used to perform a method as described herein. In the illustrated example, processing assembly 400 includes one or more reaction chambers 402, a precursor injector system 403, a first plasma gas source 404, a silicon precursor source 406, an optional second plasma gas source 408, an exhaust source 410, and a controller 412. The processing assembly 400 may comprise one or more additional gas sources (not shown), such as an inert gas source, a carrier gas source and/or a purge gas source. Reaction chamber 402 can include any suitable reaction chamber, such as an ALD or CVD reaction chamber as described herein.

The silicon precursor source 406 can include a vessel and a silicon precursor as described herein—alone or mixed with one or more carrier (e.g., inert) gases. Although illustrated with three sources 404-408, a processing assembly 400 can include any suitable number of sources. Sources 404-408 can be coupled to reaction chamber 402 via lines 414-418, which can each include flow controllers, valves, heaters, and the like. In some embodiments, each of the silicon precursor in the silicon precursor source 406, the optional reactant in the reactant source (not indicated) and/or the further reactant in the further reactant source may be independently heated or kept at ambient temperature. In some embodiments, a source vessel is heated so that a precursor or a reactant reaches a suitable temperature for vaporization.

Exhaust source 410 can include one or more vacuum pumps.

Controller 412 includes electronic circuitry and software to selectively operate valves, manifolds, heaters, pumps and other components included in the processing assembly 400. Such circuitry and components operate to introduce precursors, reactants and other gases from the respective sources. Controller 412 can control timing of gas pulse sequences, temperature of the substrate and/or reaction chamber 402, pressure within the reaction chamber 402, and various other operations to provide proper operation of the processing assembly 400. Controller 412 can include control software to electrically or pneumatically control valves to control flow of precursors, reactants and other gases into and out of the reaction chamber 402. Controller 412 can include modules such as a software or hardware component, which performs certain tasks.

Other configurations of processing assembly 400 are possible, including different numbers and kinds of precursor and reactant sources. For example, a reaction chamber 402 may comprise more than one, such as two or four, deposition stations. Such a multi-station configuration may have advantages to, for example, allow, inhibition to be performed in the same reaction chamber as depositing the material comprising silicon. Further, it will be appreciated that there are many arrangements of valves, conduits, precursor sources, and reactant sources that may be used to accomplish the goal of selectively and in a coordinated manner feeding gases into reaction chamber 402. Further, as a schematic representation of a processing assembly 400, many components have been omitted for simplicity of illustration, and such components may include, for example, various valves, manifolds, purifiers, heaters, containers, vents, and/or bypasses.

During operation of processing assembly 400, substrates, such as semiconductor wafers (not illustrated), are transferred from, e.g., a substrate handling system to reaction chamber 402. Once substrate(s) are transferred to reaction chamber 402, one or more gases from gas sources, such as precursors, reactants, carrier gases, and/or purge gases, are introduced into reaction chamber 402.

In yet another aspect, a structure formed by the methods according to the current disclosure is disclosed. In an additional aspect, a semiconductor device manufactured by using the methods according to the current disclosure is disclosed.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of depositing a material comprising silicon in a gap, the method comprising:
providing a substrate, the substrate comprising the gap, wherein the gap comprises an inner surface;
exposing the substrate to a first plasma having high ion energy to modify predetermined areas of the gap inner surface;
exposing the substrate to a second plasma having low ion energy to passivate the modified areas of the gap surface to form passivated modified areas on the gap surface; and
contacting the substrate with a vapor-phase silicon precursor to chemisorb the silicon precursor on unmodified areas of the gap for depositing material comprising silicon on the unmodified areas.

2. The method of claim 1, wherein the substrate is provided in a reaction chamber, and the substrate is exposed to the first plasma and the second plasma in the reaction chamber.

3. The method of claim 1, wherein the passivation of the modified areas comprises forming nitrogen-comprising terminations.

4. The method of claim 1, wherein the first plasma is generated from a gas selected from a group consisting of N, He, Ne, Ar, Kr and Xe.

5. The method of claim 1, wherein the second plasma comprises nitrogen.

6. The method of claim 5, wherein the second plasma is generated from a gas comprising at least one of N₂, NH₃, and N₂H₄.

7. The method of claim 1, wherein the second plasma is generated from a gas comprising at least one of He, Ne, Ar, Kr and Xe.

8. The method of claim 1, wherein the ion energy of the first plasma is at least about 15 eV.

9. The method of claim 1, wherein the ion energy of the second plasma is at most 5 eV.

10. The method of claim 1, wherein the gap inner surface comprises an oxide surface.

11. The method of claim 1, wherein the substrate comprises a silicon nitride surface.

12. The method of claim 1, wherein the silicon precursor is a nitrogen-comprising silane comprising from 1 to 4 silicon atoms.

13. The method of claim 12, wherein the silicon precursor is represented by formula Siₐ(NR₂)_{b}X_{c}, wherein a is 1, 2, 3 or 4, b+c=2a+2, b is at least 1, each R is independently selected from H, methyl, ethyl, isopropyl, tert-butyl and phenyl, and each X is independently selected from H, methyl, ethyl, isopropyl, tert-butyl, phenyl, F, Cl, Br and I.

14. The method of claim 13, wherein the silicon precursor is selected from a group consisting of SiH₃[N(CH₃)₂], SiH₃[N(CH₂CH₃)₂], SiH₃[N(CH₃)(CH₂CH₃)], SiH₃[N(C(CH₃)₃)₂], SiH₃[N(CH(CH₃)₂)₂], SiH₂[N(CH₃)₂]₂, SiH₂[N(CH₂CH₃)₂]₂, SiH₂[N(CH₃)(CH₂CH₃)]₂, SiH₂[N(C(CH₃)₃)₂]₂, SiH₂[N(CH(CH₃)₂)₂]₂, SiH(CH₃)[N(CH₃)₂]₂, SiH(CH₃)[N(CH₂CH₃)₂]₂, SiH(CH₃)[N(CH₃)(CH₂CH₃)]₂, SiH(CH₃)[N(C(CH₃)₃)₂]₂, SiH(CH₃)[N(CH(CH₃)₂)₂]₂, Si(CH₃)₂[N(CH₃)₂]₂, Si(CH₃)₂[N(CH₂CH₃)₂]₂, Si(CH₃)₂[N(CH₃)(CH₂CH₃)]₂, Si(CH₃)₂[N(C(CH₃)₃)₂]₂, Si(CH₃)₂[N(CH(CH₃)₂)₂]₂, SiH[N(CH₃)₂]₃, SiH[N(CH₂CH₃)₂]₃, SiH[N(CH₃)(CH₂CH₃)]₃, SiH[N(C(CH₃)₃)₂]₃, SiH[N(CH(CH₃)₂)₂]₃, Si[N(CH₃)₂]₄, Si[N(CH₂CH₃)₂]₄, Si[N(C(CH₃)₃)₂]₄, Si[N(CH(CH₃)₂)₂]₄, SiCl[N(CH₃)₂]₃, SiCl[N(CH₂CH₃)₂]₃, SiCl[N(CH₃)(CH₂CH₃)]₃, SiCl[N(C(CH₃)₃)₂]₃, SiCl[N(CH(CH₃)₂)₂]₃, Si[NH(CH₃)]₃—Si[NH(CH₃)]₃, Si[NH(CH₂CH₃)]₃—Si[NH(CH₂CH₃)]₃, and SiH₂(NH(CH(CH₃)₂)₂—SiH₂.

15. The method of claim 1, wherein the gap comprises a bottom, and the predetermined area modified by the first high energy plasma is the bottom.

16. The method of claim 1, wherein the chemisorption of the silicon precursor is reduced by at least 60% on the passivated modified areas relative to the unmodified areas.

17. The method of claim 1, wherein the material comprising silicon is deposited conformally on unmodified areas of the gap.

18. The method of claim 1, wherein the material comprising silicon at least partially fills the gap.

19. The method of claim 18, wherein the gap is filled from the bottom of the gap upwards.

20. A method of controlling chemisorption of a vapor-phase silicon precursor on a substrate having a surface, the method comprising:
providing the substrate in a reaction chamber;
exposing the substrate to a first plasma having high ion energy to partially modify the surface;
exposing the substrate to a second plasma having low ion energy to passivate the partially modified surface to form a partially passivated surface; and
contacting the substrate with a vapor-phase silicon precursor to chemisorb the silicon precursor on the partially passivated surface for depositing material comprising silicon on the substrate.

21. The method of claim 20, wherein the substrate comprises a gap comprising an inner surface, and wherein the first plasma partially modifies the inner surface of the gap.

22. A semiconductor processing assembly, the assembly comprising:
a reaction chamber configured and arranged to hold a substrate;
a first plasma gas source configured and arranged to contain a gas for generating at least one of a first plasma and a second plasma;
a silicon precursor source configured and arranged to contain and evaporate a silicon precursor;
a plasma generation system for generating a first plasma and a second plasma;
an injection system constructed and arranged to provide the first plasma and the second plasma into the reaction chamber; and to provide a vapor-phase silicon precursor into the reaction chamber in a vapor phase;
an exhaust; and
a controller configured and arranged to cause the system to carry out a method according to any of the preceding claims.

23. The semiconductor processing assembly of claim 22, further comprising a second plasma gas source configured and arranged to contain a gas for generating the second of the first plasma and the second plasma.
